(19) United States
(12) Patent Application Publication
(10) Pub. No.: US 2009/0170263 A1
(43) Pub. Date: Jul. 2, 2009

(54) METHOD OF MANUFACTURING FLASH MEMORY DEVICE

(76) Inventor: Ki-Min Lee, Gangnam-gu (KR)

Correspondence Address: SHERR & VAUGHN, PLLC, 620 HERNDON PARKWAY, SUITE 200, HERNDON, VA, 20170, US

(21) Appl. No.: 12/192,085

(22) Filed: Aug. 14, 2008

(30) Foreign Application Priority Data
Dec. 26, 2007 (KR) 10-2007-0137007

(51) Int. Cl. H01L 21/8247

(52) U.S. Cl. 438/261; 438/257; 257/E21.68

(57) ABSTRACT

Disclosed is a method of manufacturing a flash memory device. With this method, the surface area of a floating gate is increased by using a buffer film or a dummy pattern, without increasing the size of the flash memory device. Therefore, a coupling ratio is increased, and as a result, programming and erasure speed can be improved.

The present application claims priority under 35 U.S.C. 119 to Korean Patent Application No. 10-2007-0137007 (filed on Dec. 26, 2007), which is hereby incorporated by reference in its entirety.

### BACKGROUND

A flash memory device has the advantages of an EPROM, with programming and erasure capabilities, and an EEPROM, with has electrical erasure capabilities. A flash memory device basically stores data using one transistor per bit and can be controlled electrically to execute programming and erasure. A flash memory device as described above may have a vertically laminated gate structure in which a floating gate is formed on a silicon substrate. A multilayer gate structure includes at least one tunnel oxide film or interlayer insulating film, and a control gate formed above or around the floating gate.

In a flash memory cell described above, during the programming operation, a channel hot electron is formed on the drain side. The electron is accumulated in the floating gate, such that the threshold voltage of the cell transistor is increased. During the erasure operation of the memory cell, a high voltage is generated between the substrate and the floating gate to emit the electron accumulated in the floating gate. This decreases the threshold voltage of the cell transistor.

The floating gate plays an important role in charge characteristics of the tunnel oxide film during data programming and erasure. The floating gate also serves as a tunneling source. The floating gate is generally formed of doped polysilicon.

The interlayer insulating film preserves the charge stored in the floating gate. The interlayer insulating film is formed of an ONO (Oxide/Nitride/Oxide) film in which a lower oxide film, a nitride film, and an upper oxide film are laminated.

A voltage may be applied to the control gate to move electrons from the substrate to the floating gate or from the floating gate to the substrate. To reduce resistance, the control gate has a polycide structure in which polysilicon and metal silicide are laminated.

Recently, with higher integration of flash memory devices, the floating gate, the control gate, the source/drain, and the wiring lines of the flash memory device have become small and thin. Accordingly, a capacitance between the floating gate and the control gate is reduced, and a coupling ratio is lowered. The coupling ratio is a ratio of voltage applied to the control gate with respect to the floating gate. At present, there is a growing demand for increasing the coupling ratio without increasing the size of flash memory device.

### SUMMARY

Embodiments relate to a method of manufacturing a flash memory device, and in particular, to a method of manufacturing a flash memory device that extends a surface area of a floating gate, thereby increasing a coupling ratio. Embodiments relate to a method of manufacturing a flash memory device which includes: forming a buffer film over an upper portion of a semiconductor substrate, the semiconductor substrate having a device separation film formed in a field region; forming an opening in the buffer film to expose a floating gate region in an active region on the semiconductor substrate; forming a floating gate at the bottom and side walls of the opening; removing the buffer film, and forming a dielectric film over the semiconductor substrate including the floating gate; and forming a control gate over the dielectric film.

Embodiments relate to a method of manufacturing a flash memory device which includes: forming a dummy pattern defining a floating gate region in an active region of a semiconductor substrate, the semiconductor substrate having a device separation film formed in a field region; forming an interlayer insulating film in a region of the semiconductor substrate where no dummy pattern is formed, and removing the dummy pattern to form an opening exposing the floating gate region; forming a floating gate at the bottom and side walls of the opening; forming a dielectric film over the semiconductor substrate including the floating gate; and forming a control gate over the dielectric film.

According to embodiments, the surface area of the floating gate is increased without increasing the size of the flash memory device, thereby increasing a coupling ratio. Therefore, programming and erasure speed can be improved.

### DRAWINGS

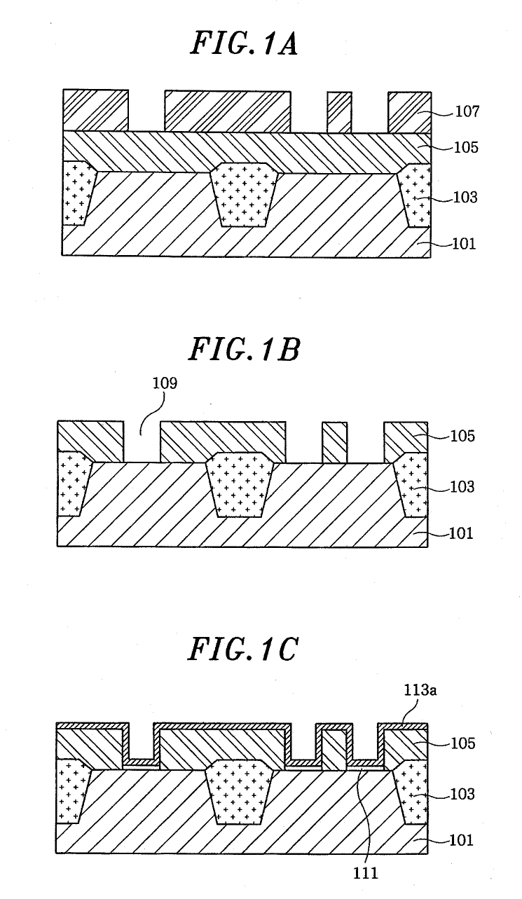

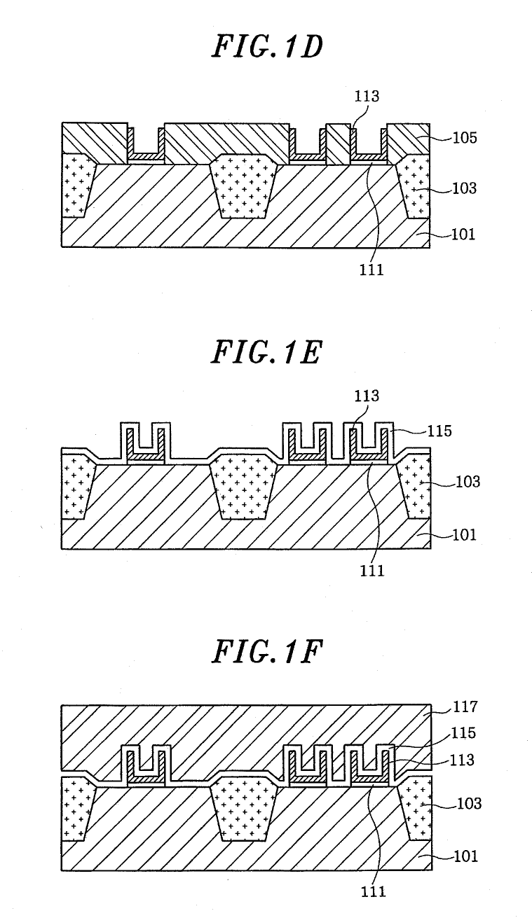

Example FIGS. 1A to 1F are sectional views illustrating a method of manufacturing a flash memory device according to embodiments.

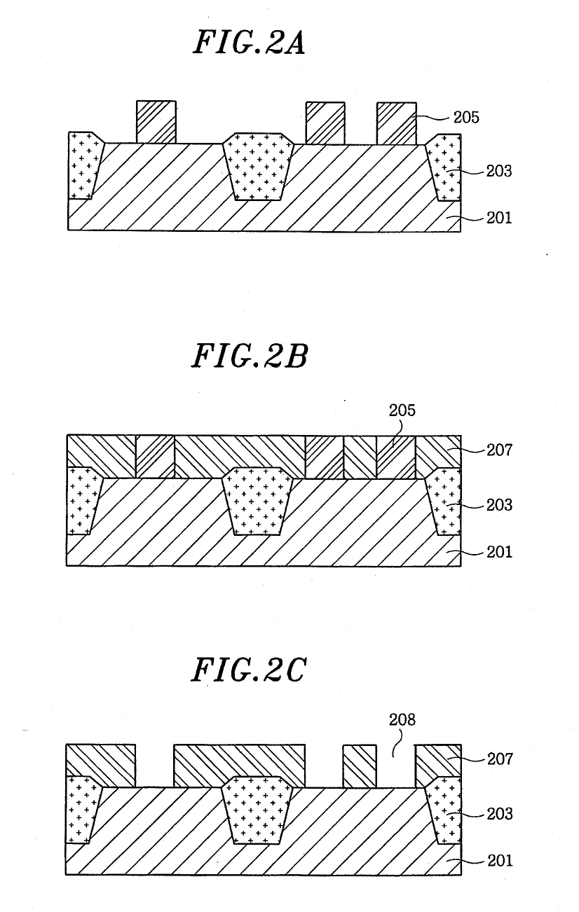

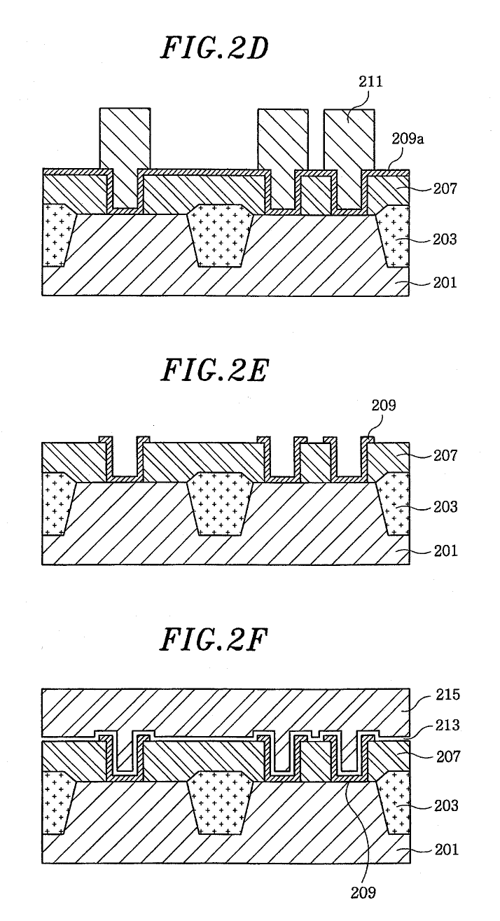

Example FIGS. 2A to 2F are sectional views illustrating a method of manufacturing a flash memory device according to embodiments.

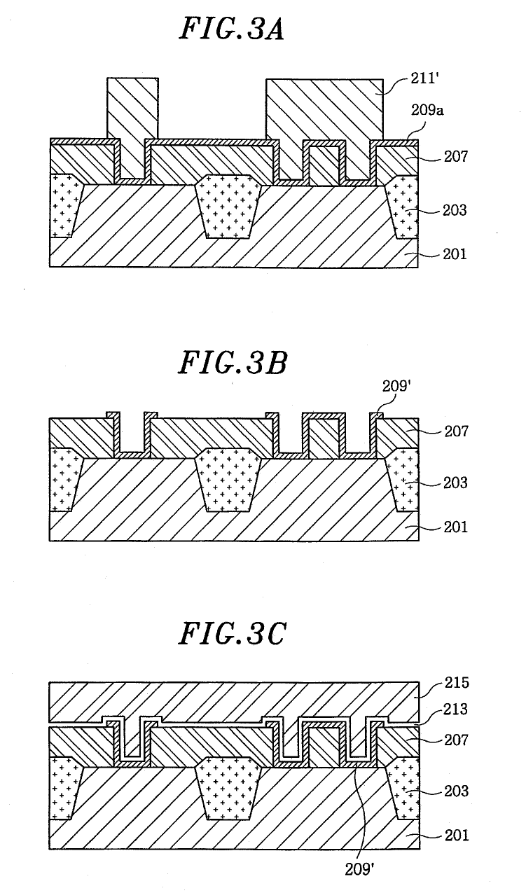

Example FIGS. 3A to 3C are sectional views illustrating a method of manufacturing a flash memory device according to embodiments.

### DESCRIPTION

Example FIGS. 1A to 1F are sectional views illustrating a method of manufacturing a flash memory device according to embodiments. Referring to example FIG. 1A, first, a trench may be formed in a field region of a semiconductor substrate 101, for example, a monocrystalline silicon substrate, by a shallow trench isolation (STI) process. Next, the trench may be filled and an active region of the semiconductor substrate 101 may be planarized. Thus, a device separation film 103 may be formed.

The process of forming the device separation film 103 will be described in detail. A buffer oxide film may be formed on the entire region of the semiconductor substrate 101, for example, a monocrystalline silicon substrate. A nitride film may be laminated over the buffer oxide film as a hard mask layer. The nitride film serves as an etch stop film in a subsequent CMP (Chemical Mechanical Polishing) process. Next, the nitride film and the buffer oxide film over the field region of the semiconductor substrate 101 may be removed by photolithography. The field region of the semiconductor substrate 101 may be etched to a predetermined depth. Thus, the trench is formed.

A liner oxide film may be formed over the surface of the semiconductor substrate 101 in the trench by thermal oxidation. This is to minimize damage in the surface of the semiconductor substrate 101 in the trench during etching to form the trench. Thereafter, an insulating film having good gap filling properties, for example, an oxide film, may be formed to a predetermined thickness filling the trench and over the nitride film. The insulating film may be formed by APCVD (Atmospheric Pressure CVD: APCVD) or HDP CVD (High Density Plasma CVD: HDP CVD). Next, the oxide film and the nitride film may be planarized by CMP. Thus, the device separation film 103 is formed in the trench.

Referring to example FIG. 1A again, a buffer film 105 may be formed over the upper portion of the entire structure. The buffer film 105 may be formed by laminating a silicon nitride film (SiNₓ) by PECVD (Plasma Enhanced Chemical Vapor Deposition: PECVD) or by laminating a polymer, such as polyimide, by spin coating. Next, a photosensitive pattern 107 may be formed over the buffer film 105 to define a floating gate region.

Referring to example FIG. 1B, the buffer film 105 may be removed by photolithography using the photosensitive pattern 107 as an etching mask. Thus, an opening 109 in the buffer film 105 may be formed. Then, the photosensitive pattern 107 may be removed. In this way, the floating gate region in the active region of the semiconductor substrate 101 may be exposed through the opening 109.

Referring to example FIG. 1C, a gate oxide film 111 may be formed over the semiconductor substrate 101 in opening 109 by thermal oxidation using the buffer film 105 as an antioxidation film. Next, a conductive layer for forming a floating gate, for example, a first polycrystalline silicon layer 113a, may be formed by CVD over the gate oxide film 111.

Referring to example FIG. 1D, the first polycrystalline silicon layer 113a may be planarized, for example, by CMP. The first polycrystalline silicon layer 113a remains at the bottom and side walls of the opening 109, but is removed in the regions over the buffer film 105. Thus, a “U” shaped floating gate 113 is formed.

Referring to example FIG. 1E, after the buffer film 105 is removed, a lower oxide film, a nitride film, and an upper oxide film may be laminated in that order over the entire region of the semiconductor substrate 101 including the floating gate 113. Thus, a dielectric film 115 having an ONO structure is formed.

When the buffer film 105 is formed of silicon nitride (SiNₓ), the buffer film 105 may be removed by wet etching or dry etching with chlorine (Cl)-based etching gas. When the buffer film 105 is formed of a polymer, it may be removed by dry etching with oxygen (O)-based etching gas. As for dry etching, a reactive ion etching apparatus may be used, which may be a plasma etching apparatus. The etching gas may be chlorine gas (Cl₂), oxygen gas (O₂), or mixed gas including nitrogen gas (N₂).

Referring to example FIG. 1F, a second polycrystalline silicon layer may be formed to a predetermined thickness over the dielectric film 115. Then, an unnecessary portion of the second polycrystalline silicon layer may be removed by photolithography. Thus, a control gate 117 is formed.

According to embodiments, the surface area of the floating gate 113 may be increased without increasing the size of the flash memory device. A capacitor including the floating gate 113, the dielectric film 115, and the control gate 117 has increased capacitance, and a coupling ratio is increased. Therefore, charge injection and erasure with respect to the floating gate 113 can be easily performed. As a result, the programming and erasure operations of the flash memory device can be smoothly performed at a low driving voltage.

Example FIGS. 2A to 2F are sectional views illustrating a method of manufacturing a flash memory device according to embodiments. Referring to example FIG. 2A, first, a trench may be formed by an STI process in a field region of a semiconductor substrate 201, for example, a monocrystalline silicon substrate. Next, the trench is filled and an active region of the semiconductor substrate 201 may be planarized. Thus, a device separation film 203 is formed.

Referring to example FIG. 2A again, a dummy pattern 205 for defining a floating gate region may be formed in the active region of the semiconductor substrate 201. The dummy pattern 205 may be formed by laminating a silicon nitride film (SiNₓ) over the entire surface of the semiconductor substrate 201 by PECVD or by laminating a polymer, such as polyimide, by spin coating. The laminated film may be patterned by photolithography with an overlying photosensitive pattern as an etching mask. If photosensitive polyimide is used, selective exposure may be performed with UV rays and patterning is performed with a developer, thereby forming a polyimide pattern. The polyimide pattern may be cured by heat treatment.

Referring to example FIG. 2B, an IMD (Inter Metallic Dielectric) film may be laminated over the upper surface of the semiconductor substrate 201 over which the dummy pattern 205 is formed, thereby forming an interlayer insulating film 207. Next, the interlayer insulating film 207 may be planarized by a planarization process, for example, CMP, such that the dummy pattern 205 is exposed. For example, the interlayer insulating film 207 may be formed of USG (Un-doped Silicate Glass) film, TEOS (Tetra Ethyl Ortho Silicate) film, or HDD (High Density Plasma) film by APCVD or SACVD (Sub-Atmospheric CVD).

Referring to example FIG. 2C, the dummy pattern 205 may be removed to form an opening 208 in the interlayer insulating film 207 to expose the floating gate region of the semiconductor substrate 201. When the dummy pattern 205 is formed of silicon nitride (SiNₓ), the dummy pattern 205 may be removed by wet etching or dry etching with chlorine (Cl)-based etching gas. When the dummy pattern 205 is formed of a polymer, it may be removed by dry etching with oxygen (O)-based etching gas. As for dry etching, a reactive ion etching apparatus may be used, which may be a plasma etching apparatus. The etching gas may be chlorine gas (Cl₂), oxygen gas (O₂), or mixed gas including nitrogen gas (N₂).

Referring to example FIG. 2D, a gate oxide film may be formed over the exposed semiconductor substrate 201 in opening 208 by thermal oxidation using the interlayer insulating film 207 as an antioxidation film. Next, a conductive layer for forming a floating gate, for example, a first polycrystalline silicon layer 209a, may be formed over the gate oxide film and the interlayer insulating film 207 by CVD. A photosensitive pattern 211 may be formed to close the floating gate region in the active region, that is, the opening 208. The photosensitive pattern 211 may be formed in a “T” shape with a predetermined margin so as to partially cover the interlayer insulating film 207 at the edge of the opening 208. When successive floating gate regions exist in the same active region, the photosensitive pattern 211 may be separated into photosensitive patterns for the respective floating gate regions.

Referring to example FIG. 2E, the first polycrystalline silicon layer 209a may be removed by photolithography with the photosensitive pattern 211 as an etching mask. The first polycrystalline silicon layer 209a remains in the floating gate forming region, that is, at the bottom and side walls of the opening 208, while the first polycrystalline silicon layer 209a over the interlayer insulating film 207 is removed. Thus, a “U” shaped floating gate 209 is formed. In this case, the photosensitive pattern 211 partially covers the interlayer insulating film 207 at the edge of the opening 208. Therefore, the floating gate 209 is formed to partially cover the interlayer insulating film 207. When successive floating gate forming regions exist in the same active region, the photosensitive pattern 211 may be separated into photosensitive patterns for the respective floating gate forming regions. Therefore, the floating gates 209 are separated from each other.

Referring to example FIG. 2F, a lower oxide film, a nitride film, and an upper oxide film may be laminated in that order over the entire region of the semiconductor substrate 201 including the floating gate 209. Thus, a dielectric film 213 having an ONO structure may be formed. A second polycrystalline silicon layer may be laminated to a predetermined thickness over the dielectric film 213. Then, an unnecessary portion of the second polycrystalline silicon layer may be removed by photolithography. Thus, a control gate 215 is formed.

According to embodiments, like the foregoing embodiments shown in FIGS. 1A-1F, the surface area of the floating gate 209 may be extended without increasing the size of the flash memory device. Thus, a capacitor having the floating gate 209, the dielectric film 213, and the control gate 215 has increased capacitance, and a higher coupling ratio. Therefore, charge injection and erasure with respect to the floating gate 209 can be more easily performed. As a result, the programming and erasure operations of the flash memory device can be smoothly performed with a low driving voltage.

Example FIGS. 3A to 3C are sectional views illustrating a method of manufacturing a flash memory device according to embodiments. The embodiments shown in example FIGS. 3A to 3C are a modification of the embodiments of example FIGS. 2A to 2F. Therefore, in example FIGS. 3A to 3C, only the processes different from example FIGS. 2A to 2F are shown in example FIGS. 3A to 3C. In example FIGS. 3A to 3C, the same elements as those in example FIGS. 2A to 2F are represented by the same reference numerals. Hereinafter, descriptions having the same technical spirit will be omitted.

Referring to example FIG. 3A, a gate oxide film may be formed over the exposed semiconductor substrate 201 in the opening 208 by thermal oxidation using the interlayer insulating film 207 as an antioxidation film. Next, a conductive layer for forming a floating gate, for example, a first polycrystalline silicon layer 209a, may be formed over the gate oxide film and the interlayer insulating film 207 by CVD. Next, a photosensitive pattern 211′ may be formed to close the floating gate forming region in the active region, that is, the opening 208. The photosensitive pattern 211′ may be formed in a “T” shape with a predetermined margin to partially cover the interlayer insulating film 207 at the edge of the opening 208. When successive floating gate regions exist in the same active region, the photosensitive patterns 211′ may be formed to be connected to each other to form a single photosensitive pattern.

Referring to example FIG. 3B, the first polycrystalline silicon layer 209a may be removed by photolithography using the photosensitive pattern 211′ as an etching mask. Then, the first polycrystalline silicon layer 209a remains in the floating gate region, that is, at the bottom and side walls of the opening 208. The first polycrystalline silicon layer 209a over the interlayer insulating film 207 is removed. Thus, a “U” shaped floating gate 209′ may be formed. In this case, the photosensitive pattern 211′ partially covers the interlayer insulating film 207 at the edge of the opening 208. Therefore, the floating gate 209′ may be formed to partially cover the interlayer insulating film 207. When successive floating gate regions exist in the same active region, since the photosensitive patterns 211′ may be connected to each other, and the floating gates 209′ may be connected to each other as a single floating gate.

Referring to example FIG. 3C, a lower oxide film, a nitride film, and an upper oxide film may be laminated in that order over the entire region of the semiconductor substrate 201 including the floating gate 209′. Thus, a dielectric film 213 having an ONO (Oxide/Nitride/Oxide) structure may be formed.

Next, a second polycrystalline silicon layer may be formed to a predetermined thickness over the dielectric film 213. Then, an unnecessary portion of the second polycrystalline silicon layer may be removed by photolithography. Thus, a control gate 215 is formed.

According to embodiments in example FIGS. 3A to 3C, like the foregoing embodiments in example FIGS. 2A to 2F and example FIGS. 1A to 1F, the surface area of the floating gate 209′ may be extended without increasing the size of the flash memory device. Thus, a capacitor having the floating gate 209′, the dielectric film 213, and the control gate 215 has increased capacitance, and a higher coupling ratio. Therefore, charge injection and erasure with respect to the floating gate 209′ can be easily performed. As a result, the programming and erasure operations of the flash memory device can be smoothly performed at a low driving voltage.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a buffer film over an upper portion of a semiconductor substrate, the semiconductor substrate having a device separation film formed in a field region;
forming an opening in the buffer film to expose a floating gate region in an active region on the semiconductor substrate;
forming a floating gate at the bottom and side walls of the opening;
removing the buffer film, and forming a dielectric film over the semiconductor substrate including the floating gate; and
forming a control gate over the dielectric film.

2. The method of claim 1, wherein the buffer film is formed by laminating a silicon nitride film.

3. The method of claim 1, wherein the buffer film is formed by laminating a polymer.

4. The method of claim 1, wherein forming the floating gate comprises:
forming a conductive layer in the opening and over the buffer film; and
planarizing the conductive layer such that the conductive layer remains at the bottom and side walls of the opening.

5. The method of claim 2, wherein forming the dielectric film comprises removing the buffer film by wet etching.

6. The method of claim 2, wherein forming the dielectric film comprises removing the buffer film by dry etching with chlorine-based etching gas.

7. The method of claim 3, wherein forming the dielectric film comprises removing the buffer film by dry etching with an oxygen-based etching gas.

8. The method of claim 1, wherein forming a dielectric film over the semiconductor substrate including the floating gate comprises laminating a lower oxide film, a nitride film, and an upper oxide film over the entire region of the semiconductor substrate including the floating gate.

9. A method comprising:
forming a dummy pattern defining a floating gate region in an active region of a semiconductor substrate, the semiconductor substrate having a device separation film formed in a field region;
forming an interlayer insulating film in a region of the semiconductor substrate where no dummy pattern is formed, and removing the dummy pattern to form an opening exposing the floating gate region;
forming a floating gate at the bottom and side walls of the opening;
forming a dielectric film over the semiconductor substrate including the floating gate; and
forming a control gate over the dielectric film.

10. The method of claim 9, wherein the dummy pattern is formed by laminating a silicon nitride film.

11. The method of claim 9, wherein the dummy pattern is formed by laminating a polymer.

12. The method of claim 10, wherein forming the opening comprises removing the dummy pattern by wet etching.

13. The method of claim 10, wherein forming the opening comprises removing the dummy pattern by dry etching with chlorine-based etching gas.

14. The method of claim 11, wherein forming the opening comprises removing the dummy pattern by dry etching with an oxygen-based etching gas.

15. The method of claim 9, wherein forming the opening comprises:
laminating an inter metallic dielectric film as the interlayer insulating film over the upper surface of the semiconductor substrate over which the dummy pattern is formed, and
planarizing the inter metallic dielectric film such that the dummy pattern is exposed.

16. The method of claim 9, wherein forming the floating gate comprises:
forming a conductive layer in the opening and over the interlayer insulating film; and
patterning the conductive layer by photolithography with a photosensitive pattern for closing the opening as an etching mask such that the conductive layer remains at the bottom and side walls of the opening.

17. The method of claim 16, wherein the photosensitive pattern is formed with a predetermined margin to partially cover the interlayer insulating film at the edge of the opening, such that the floating gate is formed to partially cover the interlayer insulating film.

18. The method of claim 16, wherein, when successive floating gate regions exist in the same active region, the photosensitive pattern is separated into photosensitive patterns for the respective floating gate regions, and separate floating gates are formed.

19. The method of claim 16, wherein, when successive floating gate forming regions exist in the same active region, photosensitive patterns for the respective floating gate regions are connected to each other, and floating gates are connected to each other as a single floating gate.

20. The method of claim 9, wherein forming a dielectric film over the semiconductor substrate including the floating gate comprises laminating a lower oxide film, a nitride film, and an upper oxide film over the entire region of the semiconductor substrate including the floating gate.
